(19) United States
(12) Patent Application Publication
(10) Pub. No.: US 2006/0253768 A1
(43) Pub. Date: Nov. 9, 2006

(54) Techniques to speculatively determine network protocol unit integrity

(75) Inventors: Steven King, Portland, OR (US); Frank L. Berry, North Plains, OR (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/121,669

(22) Filed: May 3, 2005

(51) Int. Cl. H03M 13/00

(52) U.S. Cl. 714/758

(57) ABSTRACT

Techniques to speculate boundaries of content of payload of a network protocol unit and to perform cyclical redundancy checking (CRC) on the content. The CRC validation on the content can be performed in a computing logic such as a network interface. The network protocol unit may be made available to other computing logics such as a host system. The host system may determine whether to perform another CRC validation operation on the network protocol unit.

### FIELD

The subject matter disclosed herein relates to determination of the integrity of a network protocol unit.

### RELATED ART

Network-based communications between computers are increasing in speed. Advances in network speeds, however, have not been fully utilized due, in part, to latency that may be associated with data transfer and protocol processing in computers. At least one type of protocol processing includes cyclical redundancy checking (CRC). Techniques are needed to accelerate data transfer and protocol processing speeds in computers.

### BRIEF DESCRIPTION OF THE DRAWINGS

FIG. 1A depicts a suitable system in which some embodiments of the present invention may be used.

FIG. 1B depicts examples of network protocol units.

FIG. 2A depicts an example implementation of portions of a network interface, in accordance with an embodiment of the present invention.

FIG. 2B depicts an example implementation of contents of a host memory that may be used in an embodiment of the present invention.

FIG. 3 depicts a flow diagram of a process that can be used to perform a CRC validation on a portion of content whose boundaries are speculatively determined and the content is located in a network protocol unit.

FIG. 4 depicts a flow diagram of a process that can be used to perform a CRC validation on content of a network protocol unit for which a speculative CRC validation may have previously taken place.

Note that use of the same reference numbers in different figures indicates the same or like elements.

### DETAILED DESCRIPTION

Reference throughout this specification to “one embodiment” or “an embodiment” means that a particular feature, structure, or characteristic described in connection with the embodiment is included in at least one embodiment of the present invention. Thus, the appearances of the phrase “in one embodiment” or “an embodiment” in various places throughout this specification are not necessarily all referring to the same embodiment. Furthermore, the particular features, structures, or characteristics may be combined in one or more embodiments.

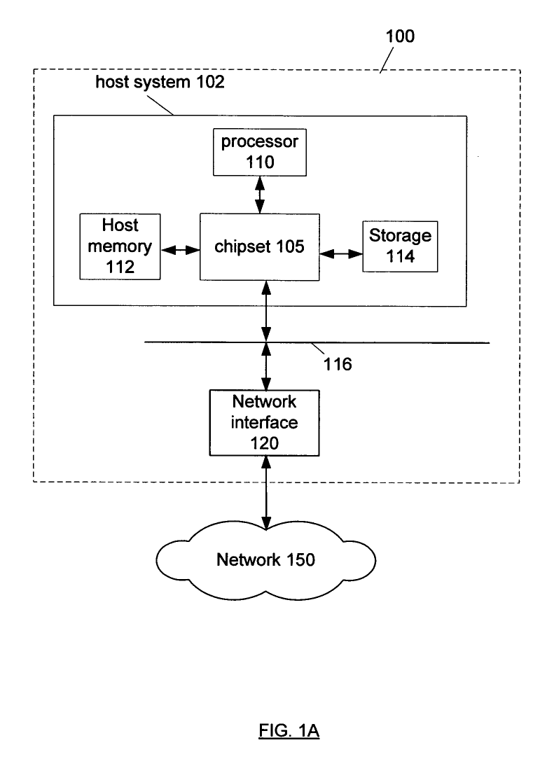

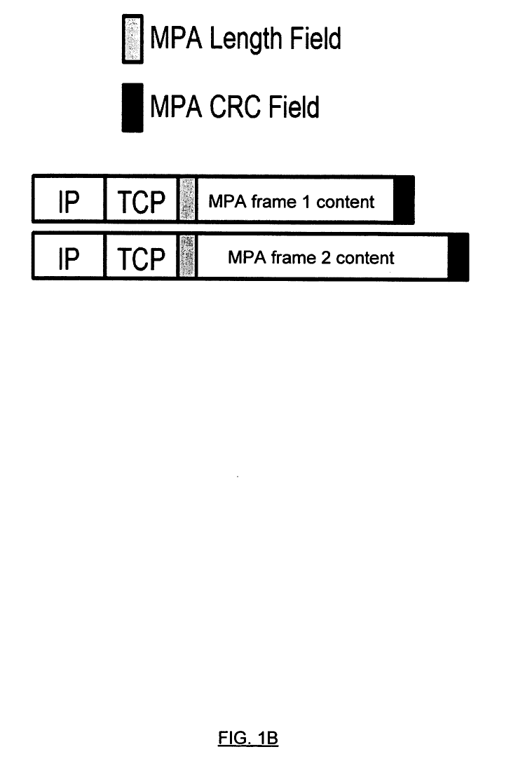

FIG. 1A depicts in computer system 100 a suitable system in which some embodiments of the present invention may be used. Computer system 100 may include host system 102, bus 116, and network interface 118.

Host system 102 may be utilized in any computing environment such as, but not limited to, a personal computer, server, switch, router, personal digital assistant, and/or mobile telephone. One embodiment of host system 102 may include chipset 105, processor 110, host memory 112, and storage 114. Chipset 105 may provide intercommunication among processor 110, host memory 112, storage 114, bus 116, as well as a graphics adapter that can be used for transmission of graphics and information for display on a display device (both not depicted). For example, chipset 105 may include a storage adapter (not depicted) capable of providing intercommunication with storage 114. For example, the storage adapter may be capable of communicating with storage 114 in conformance with any of the following protocols: Small Computer Systems Interface (SCSI), Fibre Channel (FC), and/or Serial Advanced Technology Attachment (S-ATA). In some embodiments, chipset 105 may include a direct memory access (DMA) engine to perform direct memory accesses of information within host memory.

Processor 110 may be implemented as Complex Instruction Set Computer (CISC) or Reduced Instruction Set Computer (RISC) processors, multi-core, or any other microprocessor or central processing unit.

Host memory 112 may be implemented as a volatile memory device such as but not limited to a Random Access Memory (RAM), Dynamic Random Access Memory (DRAM), or Static RAM (SRAM).

Storage 114 may be implemented as a non-volatile storage device such as but not limited to a magnetic disk drive, optical disk drive, tape drive, an internal storage device, an attached storage device, and/or a network accessible storage device.

Bus 116 may provide intercommunication among at least host system 102 and network interface 118 as well as other peripheral devices. Bus 116 may support serial or parallel communications. Bus 116 may support node-to-node or node-to-multi-node communications. Bus 116 may be compatible with Peripheral Component Interconnect (PCI) described for example at Peripheral Component Interconnect (PCI) Local Bus Specification, Revision 2.2, Dec. 18, 1998 available from the PCI Special Interest Group, Portland, Oreg., U.S.A. (as well as revisions thereof); PCI Express described in The PCI Express Base Specification of the PCI Special Interest Group, Revision 1.0a (as well as revisions thereof); PCI-x described in the PCI-X Specification Rev. 1.0a, Jul. 24, 2000, available from the aforesaid PCI Special Interest Group, Portland, Oreg., U.S.A. (as well as revisions thereof); and/or Universal Serial Bus (USB) (and related standards) as well as other interconnection standards.

Network interface 118 may be capable of providing intercommunication between host system 102 and network 120 in compliance with protocols supported by network 120. Network interface 118 may intercommunicate with host system 102 using bus 116. In one embodiment, network interface 118 may be integrated into chipset 105.

Network 120 may be any network such as the Internet, an intranet, a local area network (LAN), storage area network (SAN), a wide area network (WAN), or wireless network. Network 120 may exchange traffic with network interface 118 using the Ethernet standard (described in IEEE 802.3 and related standards) or any communications standard.

In some embodiments, computer system 100 may utilize the RDMA protocol. The RDMA protocol may use a layer above TCP/IP known as MPA to recover frame boundaries from the inbound stream of TCP/IP network protocol units and to provide a CRC validation over the recovered frame. For example, RDMA may be described in “An RDMA Protocol Specification” (version 1.0) (2002) available from the RDMA Consortium. For example, TCP/IP protocol is described at least in the publication entitled “Transmission Control Protocol: DARPA Internet Program Protocol Specification,” prepared for the Defense Advanced Projects Research Agency (RFC 793, published Sep. 1981). For example, MPA may be described at least in “Marker PDU Aligned Framing for TCP Specification” from the IETF working forum Remote Direct Data Placement Work Group (Feb. 2004) as well as revisions thereof (hereafter, “MPA specification”). As used herein, a “network protocol unit” may include any packet or frame or other format of information with a header and payload portions formed in accordance with any protocol specification.

In accordance with an embodiment of the present invention, a network interface may speculatively determine boundaries of content received in a network protocol unit and perform a CRC validation on a portion of the speculatively located content. In some embodiments, the content may include an MPA frame. Of course, boundaries of other types of payloads, packets, and frames may be speculatively determined. If the location of content is correctly speculated, a host system can use the content without further validation (e.g., CRC or other bit parity processing). Thereby, processing cycles in the host system may be used to perform operations other than CRC validation or other bit parity processing. Also delays in network protocol unit availability due to queuing of network protocol units for CRC operations or other bit parity processing can be avoided and thereby latency of availability of network protocol units may be reduced.

Computer system 100 may be implemented as any or a combination of: microchips or integrated circuits interconnected using a motherboard, hardwired logic, software stored by a memory device and executed by a microprocessor, firmware, an application specific integrated circuit (ASIC), and/or a field programmable gate array (FPGA). The term “logic” may include, by way of example, software or hardware and/or combinations of software and hardware.

FIG. 1B depicts examples of network protocol units that comply with the TCP/IP protocol and each network protocol unit carries an MPA frame in a TCP payload portion. For example, in some embodiments, each network protocol unit may include IP and TCP header portions as well as MPA frames encapsulated in TCP payload portions. An MPA frame may include an MPA length field, MPA frame content, as well as an associated MPA CRC field. The TCP payload portions (and MPA frames) may vary in size as depicted. In the depicted examples, MPA frame boundaries match the boundaries of TCP payload portions, however the MPA frame boundaries may not match boundaries of TCP payload portions. For more examples of MPA frame encapsulation, see the MPA specification.

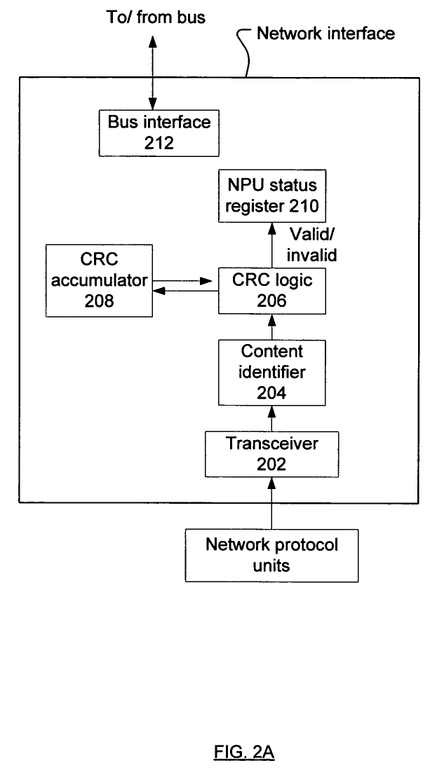

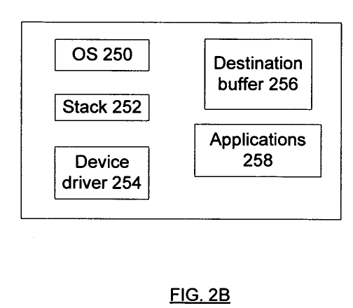

FIG. 2A depicts an example implementation of portions of a network interface, in accordance with an embodiment of the present invention. For example, the network interface may include at least transceiver 202, content identifier 204, CRC logic 206, CRC accumulator 208, network protocol unit (NPU) status register 210, and bus interface 212. Although not described in detail, network interface may include logic capable of transmitting network protocol units to a network.

Transceiver 202 may include a media access controller (MAC) and a physical layer interface (PHY) (both not depicted) capable of receiving network protocol units from a network and transmitting network protocol units to a network at any rates in conformance with applicable protocols such as Ethernet as described in IEEE 802.3 and related standards, although other protocols may be used. For example, transceiver 202 may receive and transmit network protocol units from and to a network using a physical line and/or wireless techniques.

Content identifier 204 may receive network protocol units from transceiver 202 and provide content whose boundaries are speculatively determined and located within a payload portion of each network protocol unit to CRC logic 206. For example, when a network protocol unit complies with TCP/IP, content identifier 204 may determine TCP payload location in accordance with the TCP/IP specification. In some embodiments, content identifier 204 may speculate that the boundaries of content are the same as the boundaries of a TCP payload. For example, in some embodiments, the content whose boundaries were speculatively determined may include an MPA frame. Of course, boundaries of other types of frames, packets, or other information can be speculated. Content identifier 204 may provide at least a portion of the content whose boundaries were speculatively determined to CRC logic 206 and indicate when to start and stop CRC validation.

CRC logic 206 may perform CRC validation operations on content provided by content identifier 204 (or another source). For example, provided content may include an MPA CRC field, a combination of the MPA length field and the MPA frame content, or the entire MPA frame. CRC logic 206 may store intermediate results of CRC validation operations in CRC accumulator 208 as well as use intermediate results from CRC accumulator 208 in determining CRC validation of provided content. In some embodiments, CRC accumulator 208 may store intermediate and final versions of CRC computations performed on the content. For example, CRC validation may include computation of CRC32c values in accordance with the MPA specification. CRC logic 206 may indicate whether a CRC validation operation on provided content is valid or invalid.

Network protocol unit (NPU) status register 210 may indicate whether the CRC validation operation on content of a network protocol unit whose boundaries were speculatively determined is valid or invalid. The CRC valid/invalid result in register 210 may be transferred to a host computer (or other destination) as meta data. The meta data may be stored in the same region of host memory as that of the associated network protocol unit or in another region of host memory.

Bus interface 212 may provide intercommunication with a bus. Such bus may include but is not limited to a bus similar to bus 116 (FIG. 1A). For example, the bus may provide intercommunication between the network interface and the host system. Bus interface 212 may comply with standards supported by the bus (although other interconnection standards may be used). For example, bus interface 212 may include and utilize a direct memory access (DMA) engine (not depicted) to perform direct memory accesses of information from host memory and/or host storage into the network interface and/or from the network interface into host memory and/or host storage. For example, bus interface 212 may be used at least to transfer network protocol units and meta data to the host system.

FIG. 2B depicts an example implementation of contents of a host memory utilized by a host system that may be used in an embodiment of the present invention. For example, the host memory may store operating system (OS) 250, stack 252, device driver 254, destination buffer 256, and applications 258. For example the host system may at least receive network protocol units and meta data from a network interface. The meta data may indicate whether a CRC validation operation performed on a portion of content of a network protocol unit provided a valid or invalid result, where the boundaries of the content were speculatively determined.

Suitable embodiments of OS 250 include, but are not limited to, operating systems compatible with Linux™ or Microsoft Windows®.

Stack 252 may perform protocol processing at least on network protocol units received from a network and/or information to be transmitted to a network both in accordance with RDMA, TCP/IP, and/or MPA protocol specifications. For example, in some embodiments, stack 252 may perform CRC validation operations on payload portions of network protocol units received from a network. In some embodiments, stack 252 may be integrated into OS 250.

Device driver 254 may be a device driver for a network interface. Device driver 254 may at least coordinate the transfer of network protocol units (or portions thereof) as well as other information between host system and network interface.

Destination buffer 256 may store data (e.g., network protocol units (or portions thereof)) received by a network interface for example from a network.

Applications 258 can be one or more logic that may utilize data at least received from a network or transferred to a network. An application may include, but not be limited to, for example, a web browser, input/output filter, an e-mail serving application, a file serving application, or a database application.

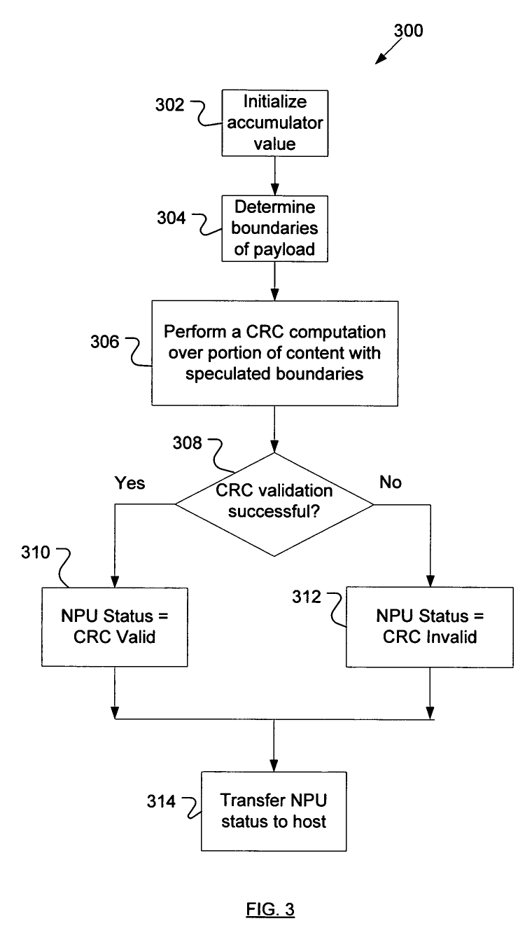

FIG. 3 depicts a flow diagram of a process that can be used by a network interface or other logic to perform a CRC validation on a portion of content whose boundaries are speculatively determined and the content is located in a network protocol unit. For example, the content may include an MPA frame (or other information). Process 300 of FIG. 3 may be performed by any computing logic capable of receiving network protocol units from a network and capable of providing network protocol units to another computing logic, such as a host system.

In block 302, process 300 may initialize a CRC accumulator value. The CRC accumulator value may represent a CRC value prior to CRC being performed over portion of content whose boundaries are speculatively determined. For example, an initialized accumulator value may be OxFFFFFFFF, which represents the initialized value pursuant to the MPA specification, although other values may be used in initialization.

In block 304, process 300 may locate boundaries of a payload portion of a network protocol unit. For example, a network protocol unit may include TCP header and TCP payload portions and the payload portion may be a TCP payload portion. In block 304, process 300 may determine the size of the TCP header and based on such determination, locate a start of the TCP payload portion. For example, in some embodiments, a TCP header may vary in length from forty (40) to sixty (60) bytes, although other sizes may be used. For example, one or more bits in the TCP header may indicate a length of the TCP header. Based on the indication, the TCP header length may be determined as well as the start of the TCP payload. For example, from the determined start of the TCP payload to the end of the network protocol unit may be the TCP payload.

In block 306, process 300 may perform a CRC computation over a portion of content with speculated boundaries from the payload portion of the network protocol unit. For example, in some embodiments, process 300 may speculate that boundaries of an MPA frame, which may include a combination of an MPA length field, MPA frame content, and MPA CRC field, are the same as boundaries of the TCP payload. In some embodiments, the portion of content over which a CRC computation is performed may be merely the MPA CRC field, a combination of the MPA length field and the MPA frame content, or the entire MPA frame. For example, the MPA length field and MPA CRC field may have known sizes and positions within an MPA frame. For example, the MPA CRC field may be the last four bytes of the MPA frame.

Results of the CRC computation may be provided in a CRC accumulator. The CRC computation may be performed byte or word wise. For example, a suitable CRC computation scheme is described for example in the MPA specification, although other CRC computation schemes may be used.

In block 308, process 300 may determine whether the CRC computation on portions of content whose boundaries were speculated was successful. For example, when the MPA CRC field or the entire MPA frame (including the MPA CRC field) is used in a CRC computation, the result of the CRC computation may indicate a valid CRC is the result matches an expected quantity. For example, when the MPA frame excluding the MPA CRC field is used in a CRC computation, the result of the CRC computation may indicate a valid CRC if the result matches the excluded MPA CRC field. If a valid CRC results, then block 310 follows block 308. In block 310, a network protocol unit status may be indicated as CRC valid. If a valid CRC does not result, then block 312 follows block 308. In block 312, a network protocol unit status may be indicated as CRC invalid. Block 314 may follow blocks 310 and 312.

In block 314, process 300 may transfer the network protocol unit status to the host. For example, the network protocol unit may be transferred to the host system with meta data associated with the network protocol unit. The meta data may indicate whether the CRC performed on portion of content whose boundaries were speculatively determined is valid or invalid.

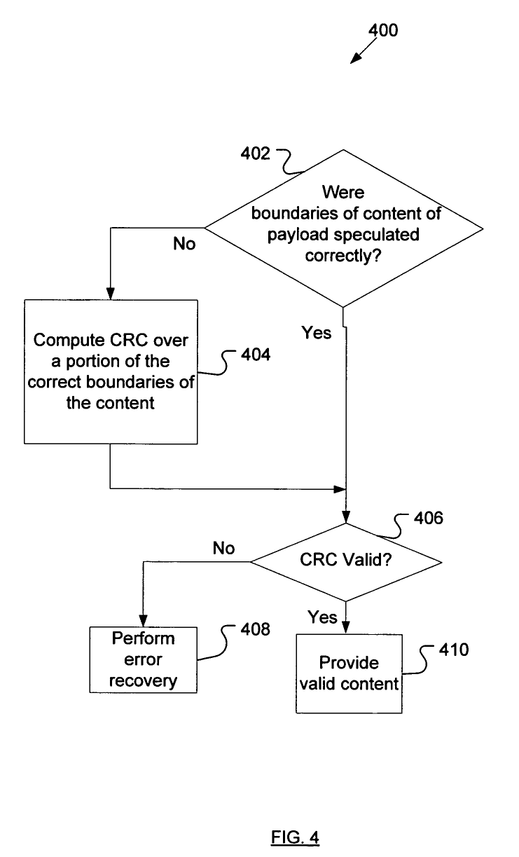

FIG. 4 depicts a flow diagram of a process that can be used by a protocol processing stack to perform a CRC validation on a portion of content of a network protocol unit for which a CRC validation may have previously taken place. For example, process 400 may be utilized by stack 152, although other logic may utilize process 400. Process 400 of FIG. 4 may be performed by any computing logic.

In block 402, process 400 may determine whether boundaries of content of a payload portion of a network protocol unit were speculated correctly. For example, a network interface or other computing logic may have speculated the boundaries of content of a payload portion of a network protocol unit. For example, content of the payload portion may correspond to an MPA frame.

For example, block 402 may determine the correct boundaries of content of the payload portion of the network protocol unit. For example, when the content is an MPA frame, block 402 may determine (1) whether the beginning of the TCP payload matches the beginning of an MPA frame and (2) whether the end of the TCP payload matches the end of the MPA frame. If any of (1) or (2) is false, then the boundaries of the content were not correctly speculated and block 404 may follow block 402. If (1) and (2) are true, then the boundaries of the content were correctly speculated and block 406 may follow block 402. For example, block 406 may follow a condition where the content boundaries were correctly speculated.

For example, in block 402, process 400 may compute boundaries of the TCP payload in accordance with the TCP/IP specification. For example, in block 402, process 400 may compute boundaries of the MPA frame in accordance with the MPA specification and MPA state information. The MPA state information may include information pertinent to the session in which the network protocol unit was transmitted. For example, the MPA state may indicate a TCP/IP sequence number of the MPA frame as well as frame boundaries of the MPA frame. For example, a session may correspond to an RDMA connection. For example, the MPA state may be computed in accordance with the MPA specification.

For example, a TCP payload may not match boundaries of an MPA frame when a sender sent misaligned (or packed) MPA frame or re-segmentation was performed before forwarding the packet to the network interface thereby causing loss of MPA frame alignment.

In block 404, process 400 may compute a CRC over a portion of the correct boundaries of the content in the payload of the network protocol unit. For example, the correct boundaries of the MPA frame may have been determined in block 402. For example, CRC validation may include using CRC computation techniques similar to those described in block 306 of FIG. 3.

In block 406, process 400 may determine whether the CRC applied over the content of interest corresponds to a valid CRC. The content of interest may correspond to the portion of content over which a CRC was performed. For example, if the host determines that the boundaries of the MPA frame match the boundaries of the TCP payload (as determined in block 402), then an indication of a valid CRC over correctly speculated boundaries may correspond to a valid CRC for the content. For example, for CRC computations performed in block 404, a valid CRC for the content of interest may be determined in a similar manner as that described in block 308. If the CRC for the content of interest is not valid, block 408 may follow block 406. If the CRC for the content of interest is valid, block 410 may follow block 406.

In block 408, process 400 may perform error recovery on the content. For example, error recovery may be performed on the MPA frame. For example, the error recovery may include an MPA error recovery scheme in accordance with the MPA specification. In block 410, process 400 may provide the CRC valid content for use by an application or other protocol processing layers. For example, the content may include an MPA frame.

Embodiments of the present invention may be implemented as any or a combination of: microchips or integrated circuits interconnected using a motherboard, hardwired logic, software stored by a memory device and executed by a microprocessor, firmware, an application specific integrated circuit (ASIC), and/or a field programmable gate array (FPGA).

The drawings and the forgoing description gave examples of the present invention. Although depicted as a number of disparate functional items, those skilled in the art will appreciate that one or more of such elements may well be combined into single functional elements. Alternatively, certain elements may be split into multiple functional elements. Elements from one embodiment may be added to another embodiment. For example, orders of processes described herein may be changed and are not limited to the manner described herein. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A method comprising:
receiving at a first computing logic a network protocol unit from a network;
at the first computing logic, speculating boundaries of content of the network protocol unit;
at the first computing logic, performing a cyclical redundancy checking (CRC) validation on a portion of the content having speculated boundaries; and
at the first computing logic, providing an indication whether the CRC of the content is valid or invalid.

2. The method of claim 1, wherein the speculating boundaries comprises:
setting boundaries of the content as boundaries of a payload portion of the network protocol unit.

3. The method of claim 1, wherein the portion of the content comprises an MPA CRC field.

4. The method of claim 1, wherein the portion of the content comprises a combination of an MPA length field and MPA frame contents.

5. The method of claim 1, further comprising:
at a second computing logic, receiving both the network protocol unit and the indication from the first computing logic; and
at the second computing logic, selectively providing the content in response to the speculated boundaries being correctly determined and the indication that the CRC is valid.

6. The method of claim 1, further comprising
at a second computing logic, receiving both the network protocol unit and the indication from the first computing logic; and
at the second computing logic, selectively performing an MPA error recovery on the content in response to the speculative boundaries being correctly determined and the indication that the CRC is not valid.

7. The method of claim 1, further comprising
at a second computing logic, receiving both the network protocol unit and the indication from the first computing logic; and
at the second computing logic, selectively performing a CRC validation using correct boundaries of the content in response to boundaries of the content having been speculated incorrectly.

8. The method of claim 1, wherein the first computing logic comprises a network interface.

9. A method comprising:
receiving a network protocol unit and an indication of whether a cyclical redundancy checking (CRC) validation on content with speculated boundaries was valid or invalid; and
determining whether boundaries of the content were speculated correctly.

10. The method of claim 9, wherein the content comprises an MPA frame.

11. The method of claim 9, wherein the speculated boundaries comprises boundaries of a payload portion of the network protocol unit.

12. The method of claim 9, further comprising
selectively performing another CRC validation using correct boundaries of the content in response to boundaries of the content having been speculated incorrectly.

13. The method of claim 9, further comprising:
selectively providing the content in response to the speculated boundaries being correctly determined and the indication the CRC is valid.

14. The method of claim 9, further comprising
selectively performing an MPA error recovery in response to the indication the CRC is not valid.

15. A computer-readable medium comprising instructions stored thereon which when executed by a machine cause the machine to:
at a first computing logic, receive a network protocol unit from a network;
at the first computing logic, speculate boundaries of content of the network protocol unit;
at the first computing logic, perform a cyclical redundancy checking (CRC) validation on a portion of the content having speculated boundaries; and
at the first computing logic, provide an indication whether the CRC of the content is valid or invalid.

16. The computer-readable medium of claim 15, wherein the instruction to speculate comprises an instruction to:
set boundaries of the content as boundaries of a payload portion of the network protocol unit.

17. The computer-readable medium of claim 15, wherein the portion of the content comprises an MPA CRC field.

18. The computer-readable medium of claim 15, wherein the portion of the content comprises a combination of an MPA length field and MPA frame contents.

19. A computer-readable medium comprising instructions stored thereon which when executed by a machine cause the machine to:
receive a network protocol unit and an indication of whether a cyclical redundancy checking (CRC) validation on content with speculated boundaries was valid or invalid; and
determine whether boundaries of the content were speculated correctly.

20. The computer-readable medium of claim 19, wherein the content comprises an MPA frame.

21. The computer-readable medium of claim 19, wherein the speculated boundaries comprises boundaries of a payload portion of the network protocol unit.

22. The computer-readable medium of claim 19, further comprising instructions stored thereon which when executed by a machine cause the machine to:
selectively perform another CRC validation using correct boundaries of the content in response to boundaries of the content having been speculated incorrectly.

23. The computer-readable medium of claim 19, further comprising instructions stored thereon which when executed by a machine cause the machine to:
selectively provide the content in response to the speculated boundaries being correctly determined and an indication the CRC is valid.

24. The computer-readable medium of claim 19, further comprising instructions stored thereon which when executed by a machine cause the machine to:
selectively perform an MPA error recovery in response to an indication the CRC is not valid.

25. A system comprising:
a host system comprising a processor and a memory device;
a bus; and
a chipset to communicatively couple the host system to the bus, wherein the chipset comprises a network interface and wherein the network interface comprises logic to:
receive a network protocol unit from a network;
speculate boundaries of content of the network protocol unit;
perform a cyclical redundancy checking (CRC) validation on a portion of the content having speculated boundaries; and
provide an indication whether the CRC of the content is valid or invalid.

26. The system of claim 25, wherein the host system comprises logic to:
receive the network protocol unit and the indication of whether the CRC validation on content with speculated boundaries was valid or invalid; and
determine whether boundaries of the content were speculated correctly.

27. The system of claim 25, wherein the content comprise an MPA frame.

28. The system of claim 25, wherein the bus is compatible with PCI.

29. The system of claim 25, wherein the bus is compatible with PCI express.
